(19) United States
(12) Patent Application Publication
(10) Pub. No.: US 2015/0242308 A1
(43) Pub. Date: Aug. 27, 2015

(54) ACCELERATION SYSTEM IN 3D DIE-STACKED DRAM

(71) Applicants: ELECTRONICS AND TELECOMMUNICATIONS RESEARCH INSTITUTE, Daejeon (KR); UNIST ACADEMY-INDUSTRY RESEARCH CORPORATION, Ulsan (KR)

(72) Inventors: Yong Joo KIM, Daejeon (KR); Jin Yong LEE, Seoul (KR); Yun Heung PAEK, Seoul (KR); Jong Eun LEE, Ulsan (KR)

(21) Appl. No.: 14/610,040

(22) Filed: Jan. 30, 2015

(30) Foreign Application Priority Data
Feb. 24, 2014 (KR) 10-2014-0021342

(51) Int. Cl. G06F 12/02; H01L 25/00; G06F 11/27; H01L 21/768; G06F 12/08; H01L 25/18; H01L 23/48

(52) U.S. Cl. CPC G06F 12/0238; H01L 25/18; H01L 25/50; H01L 23/481; H01L 21/76898; G06F 12/0806; G06F 11/27; G06F 2212/251; G06F 2212/62

(57) ABSTRACT

Provided is a memory device including a logic layer including at least one of a peripheral device, an interface, and a built-in self-test (BIST) module and a reconfigurable accelerator (RA), and at least one data layer to store data, wherein the RA is positioned in a vacant space of the logic layer and processes at least a portion of a task processed by the memory device.

### CROSS-REFERENCE TO RELATED APPLICATION

This application claims the priority benefit of Korean Patent Application No. 10-2014-0021342, filed on Feb. 24, 2014, in the Korean Intellectual Property Office, the disclosure of which is incorporated herein by reference.

### BACKGROUND

1. Field of the Invention The present invention relates to a method of configuring a memory architecture used in a system on a chip (SoC) field or an embedded system field, and more particularly, to an acceleration system and method in a three-dimensional (3D) die-stacked dynamic random access memory (DRAM).

2. Description of the Related Art Die-stacking technology includes stacking dies in layers to integrate a large capacity in a small space and enable a fast interconnection between the dies.

Among three-dimensional (3D) stacking methods, using a through-silicon via (TSV) to connect dies may be a fast method to obtain a high degree of integration.

When using the TSV, a vacant space may be formed in a logic layer, but left wastefully unused. Recently, research has been conducted on utilizing the space.

### SUMMARY

According to an aspect of the present invention, there is provided a memory device including a logic layer including at least one of a peripheral device, an interface, and a built-in self-test (BIST) module and a reconfigurable accelerator (RA), and at least one data layer to store data. The RA may be positioned in a vacant space of the logic layer and process at least a portion of a task to be processed by the memory device.

The RA may include processing elements (PEs), and the PEs may be connected to one another to be in a form of an array structure.

A first PE may be connected to a second PE adjacent to the first PE, and transmit and receive the data with the second PE.

A PE may include a functional unit (FU) to calculate the data.

The logic layer may include a local memory.

The local memory may include a first local cache including a plurality of caches, and a second local cache to connect the data layer to the first local cache.

When the RA does not operate, the second local cache may be used as a row buffer of the data layer.

A size of the logic layer may be identical to a size of the data layer.

A first area including at least one of the peripheral device, the interface, and the BIST module may be positioned at a center of the logic layer.

The logic layer may be disposed below the data layer.

According to another aspect of the present invention, there is provided a memory device including at least one data layer to store data and a logic layer disposed below the at least one data layer. The logic layer may include a first area including at least one of a peripheral device, an interface, and a BIST module, and a second area including an RA.

The first area may be positioned at a center of the logic layer, and the second area may be a remaining area in the logic layer from which the first area is excluded.

The logic layer and the at least one data layer may be stacked using a through-silicon via (TSA).

The logic layer may include a local memory.

The local memory may include a first local cache including a plurality of caches, and a second local cache to connect the data layer to the first local cache.

According to still another aspect of the present invention, there is provided a method of preparing a memory device including forming a logic layer including a peripheral device, an interface, and a BIST module, and also an RA, and forming at least one data layer storing data. The RA may be positioned in a vacant space of the logic layer and process at least a portion of a task to be processed by the memory device.

The logic layer and the at least one data layer may be stacked using a TSV.

The method of preparing the memory device may further include forming PEs in the RA to be in an array structure.

The method of preparing the memory device may further include forming a local memory in the logic layer.

The method of preparing the memory device may further include forming, in the local memory, a first local cache including a plurality of caches and forming, in the local memory, a second local cache connecting the data layer to the first local cache.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating a configuration of a memory device according to an embodiment of the present invention;

FIG. 2 is a block diagram illustrating a configuration of a logic layer according to an embodiment of the present invention;

FIG. 3 is a block diagram illustrating a configuration of a reconfigurable accelerator (RA) and a configuration of processing elements (PEs) according to an embodiment of the present invention;

FIG. 4 is a block diagram illustrating a configuration of a memory device according to another embodiment of the present invention;

FIG. 5 is a block diagram illustrating a configuration of a memory device according to still another embodiment of the present invention;

FIG. 6 is a flowchart illustrating a method of preparing a memory device according to an embodiment of the present invention;

FIG. 7 is a flowchart illustrating an operation of forming a logic layer according to an embodiment of the present invention; and

FIG. 8 is a flowchart illustrating an operation of forming a second area according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the accompanying drawings, however, the present invention is not limited thereto or restricted thereby.

When it is determined a detailed description related to a related known function or configuration that may make the purpose of the present invention unnecessarily ambiguous in describing the present invention, the detailed description will be omitted here. Also, terms used herein are defined to appropriately describe the exemplary embodiments of the present invention and thus may be changed depending on a user, the intent of an operator, or a custom. Accordingly, the terms must be defined based on the following overall description of this specification.

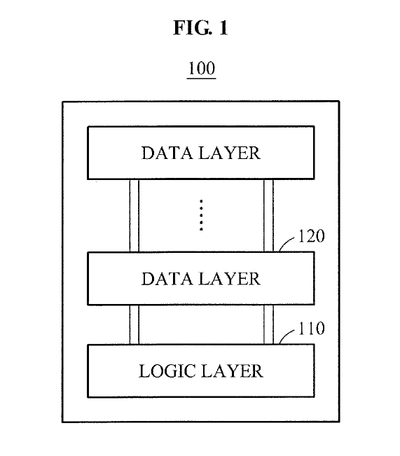

FIG. 1 is a block diagram illustrating a configuration of a memory device 100 according to an embodiment of the present invention.

The memory device 100 may refer to a device to maintain data temporarily or permanently. The memory device 100 may also be referred to as a storage device. A memory may be frequently confused with a “memory unit,” but generally refer to a main memory unit or a random access memory (RAM).

The memory device 100 may be classified as a non-volatile memory (NVM) and a volatile memory based on volatility. The NVM or an NVRAM may refer to a memory that continuously maintains stored information despite power not being supplied. Dissimilar to the NVM that does not require a continuous supply of electric power, the volatile memory may refer to a memory requiring electric power to maintain stored information and also be referred to as a temporary memory. A representative example of the volatile memory is a RAM including a dynamic RAM (DRAM) and a static RAM (SRAM).

Referring to FIG. 1, the memory device 100 includes a logic layer 110 and a data layer 120. The data layer 120 may include a DRAM.

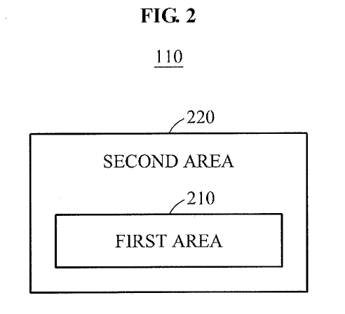

The logic layer 110 may include at least one of a peripheral device, an interface, a built-in self-test (BIST) module, and a reconfigurable accelerator (RA). In the memory device 100, an area including at least one of the peripheral device, the interface, and the BIST module may differ from an area including the RA. For example, at least one of the peripheral device, the interface, and the BIST module may be included in a first area of the logic layer 110, and the RA may be included in a second area of the logic layer 110. In such an example, the first area may be positioned at a center of the logic layer 110, and the second area may indicate a remaining area in the logic layer 110 from which the first area is excluded. Detailed descriptions will be provided with reference to FIG. 2.

The memory device 100 may include at least one data layer 120 to store data. The data layer 120 may indicate a DRAM layer.

For example, when the logic layer 110 includes at least one of the peripheral device, the interface, and the BIST module, the logic layer 110 may have a vacant space, also referred to as an unused space. A three-dimensional (3D) stack DRAM may have a structure in which different layers are stacked and thus, heat may not be easily emitted when compared to a two-dimensional (2D) DRAM.

The RA may include processing elements (PEs), and the PEs may be connected to one another to be in a form of an array structure. The RA may be a type of an accelerator having a structure to accelerate a simple calculation. Due to having a simple structure the RA may occupy a relatively small space and consume a relatively lower amount of electric power.

The RA may include at least one PE. In an example, a first PE may be connected to a second PE adjacent to the first PE. The first PE and the second PE may receive and transmit data therebetween. The PEs may achieve a relatively high degree of performance and be suitable to accelerate a data intensive kernel.

In addition, a PE may include a functional unit (FU) to perform a data calculation. The PE may include the FU such as an arithmetic and logic unit (ALU). The first PE may perform calculations by receiving data independently or from an adjacent PE, for example, the second PE.

When the RA is disposed in the vacant space, even a small area of the vacant space may be utilized. The RA may access a large quantity of data without a delay because the RA generates less heat and has a high data bandwidth.

The logic layer 110 may access the data internally and quickly by being attached immediately next to a data cell of the DRAM. When the logic layer 110 processes data, a high data bandwidth may be secured through an internal connection and thus, a fast access to the data may be achieved.

The logic layer 110 may include a local memory. The local memory may include a first local cache and a second local cache.

The first local cache may include a plurality of caches. The second local cache may connect the data layer 120 to the first local cache.

The local memory including the first local cache and the second local cache may effectively assist the RA and the data layer 120.

When the RA does not operate, the second local cache may be used as a row buffer of the data layer 120.

A size of the logic layer 110 may be identical to a size of the data layer 120. The logic layer 110 and the data layer 120 may be stacked with the sizes of the both to be identical so as to secure stability in a stacking method using a through-silicon via (TSV).

In an example, the method using the TSV may include combining a plurality of DRAM layers and combining the combination of the DRAM layers with a single complementary metal-oxide-semiconductor (CMOS) layer to include a DRAM peripheral circuitry, an interface circuitry, and a BIST module, and other components.

In another example, the logic layer 110 and the data layer 120 may be fabricated through different processes. The logic layer 110 and the data layer 120 fabricated through the different processes may be connected using the TSV method. The connected logic layer 110 and the data layer 120 may be included in the memory device 100. The memory device 100 may demonstrate a fast response speed and an optimized process may enable accumulation of a large quantity of data.

Although a large area is not a necessity for actually required circuitries in the logic layer 110, equalizing the sizes of the logic layer 110 and the data layer 120 may effectively increase an output.

Thus, when forming the size of the logic layer 110 to be identical to the size of the data layer 129, the vacant space may be generated in the logic layer 110.

The logic layer 110 may be disposed below the data layer 120.

FIG. 2 is a block diagram illustrating a configuration of the logic layer 110 according to an embodiment of the present invention.

Referring to FIG. 2, the logic layer 110 includes a first area 210 and a second area 220. The first area 210 includes at least one of a peripheral device, an interface, and a BIST module in the logic layer 110. The first area 210 may be positioned at a center of the logic layer 110. The second area 220 includes an RA. The second area 220 may be a remaining area in the logic layer 110 from which the first area 210 is excluded.

The logic layer 110 may include a local memory. The local memory may include a first local cache including a plurality of caches, and a second local cache connecting the data layer 120 and the first local cache.

In the second area 220, which is a vacant space of the logic layer 110, the RA may be included to improve performance at no additional cost. Here, a low-power RA may be suitable for a DRAM environment. Due to a close proximity to a DRAM layer, a memory bottle-neck issue, which is considered a major issue limiting performances of the RA, may be resolved.

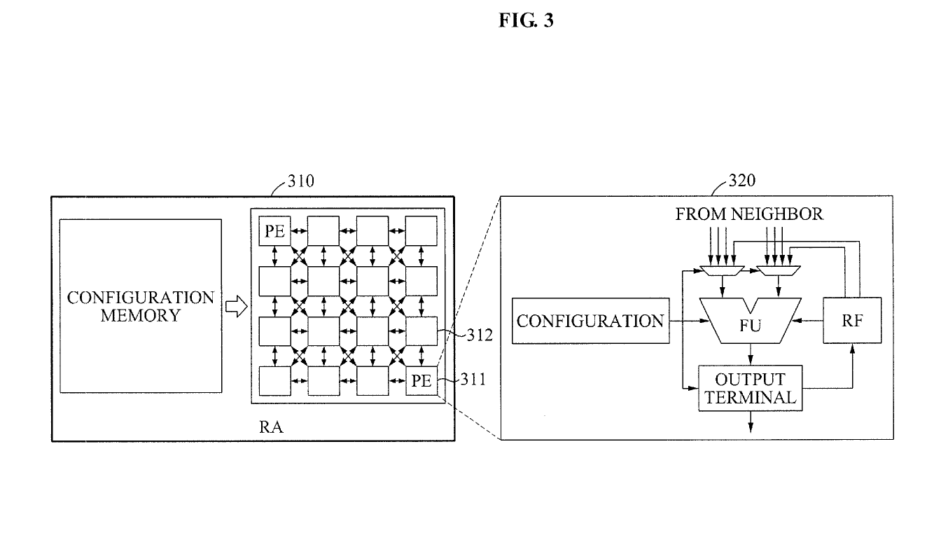

FIG. 3 is a block diagram illustrating a configuration of an RA 310 and a configuration of PEs according to an embodiment of the present invention.

Referring to FIG. 3, the RA 310 includes at least one PE to perform a task that may include storing data or calculating the data. Each PE may be connected to a neighboring PE to perform the task by receiving and transmitting the data therebetween. For example, a first PE 311 may be connected to a second PE 312, and transmit and receive data therebetween.

In such an example, a task to be performed in the PEs may also be referred to as a configuration. The configuration may be stored in a configuration memory and transmitted to each PE. In addition, another task may be performed by changing the configuration, which may be indicated as “reconfigurable.”

Referring back to FIG. 3 illustrating an example 320 of a detailed configuration of the first PE 311, the first PE 311 includes an FU such as an ALU. For example, the FU included in the first PE 311 may perform a data calculation by receiving the data from the second PE 312. Subsequent to the data calculation, the FU may transmit a result of the calculation to an output terminal. The output terminal may transmit the result of the calculation to another PE or the first PE 311 again. A PE may perform a data calculation by receiving the data from a neighboring PE or independently. In addition, the PE may not have peripherals, for example, a branch unit, which may be accompanied with a general central processing unit (CPU) and thus, a size of the PE may be reduced and the PE may consume a relatively lower amount of power compared to a calculating workload.

In the example 320, a register file (RF) may refer to a space used to store intermediate values generated during the calculation. A PE may perform a task, or a configuration. Data used for the performance of the PE may be received from a neighboring PE or from the RF of the PE. The PE may transmit a result value to the output terminal to transmit the result value to another PE or store the result value in the RF to be used later.

In an example, when a DRAM accelerator performs a data intensive kernel, the DRAM accelerator may use a task by offloading the task from the CPU. When the DRAM accelerator performs the data intensive kernel, data may not need to be transferred through a bus and thus, off-chip data transfer overhead may be eliminated. Accordingly, an amount of power consumed by the bus may be reduced and performance may be improved. In addition, when a general task is performed, the CPU may perform the task without using the DRAM accelerator.

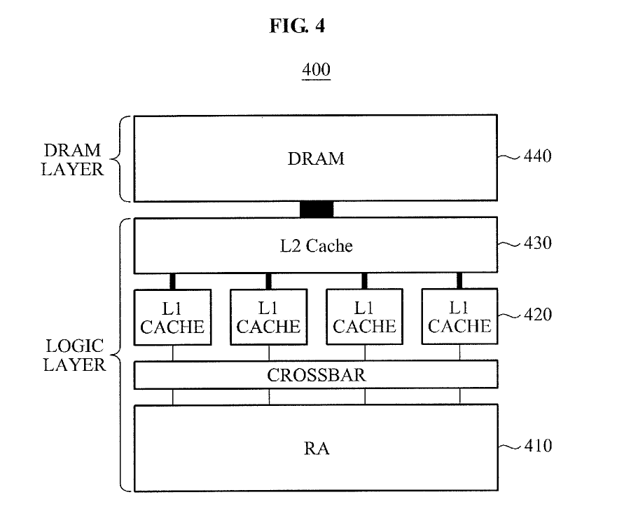

FIG. 4 is a block diagram illustrating a configuration of a memory device 400 according to another embodiment of the present invention.

Referring to FIG. 4, the memory device 400 includes a logic layer and a data layer. The data layer may be a DRAM layer 440.

In an example, an RA 410 of the memory device 400 may use a cache as a local memory. The local memory may be configured in two steps. For example, the local memory may include a first local (L1) cache 420 and a second local (L2) cache 430. The L1 cache 420 may include a plurality of small caches. In such an example, the L1 cache 420 includes a plurality of the small caches to process simultaneously occurring data requests because the RA 410 requests a plurality of sets of data to the local memory.

In addition, the logic layer may include a crossbar. The crossbar may distribute a plurality of input values and a plurality of output values of the L1 cache 420 including the small caches to prevent a collision between the values.

Due to a long access time and a large amount of power consumption involved with a DRAM access, the L2 cache 430 may be interposed between the LI cache 420 and the DRAM layer 440 to reduce the access time and the amount of power consumption. When the RA 410 operates, the L2 cache 430 may be used as the local memory for a general type of the RA 410.

However, when the RA 410 does not operate, the L2 cache 430 may be used as a row buffer cache to temporarily store data of a row of a DRAM for CPUs in another chip. A block size of the L2 cache 430 may be designed to include a portion or an entirety of a row buffer.

When the local memory includes the caches, off-chip communication required to manage data in statistical parametric mapping (SPM) may be eliminated and thus, an amount of power consumed in a bus and an additional amount of time for performance may be reduced. In case of an RA using the SPM may exclusively perform a kernel code having a regular access pattern to arrange data in the SPM in advance. However, in a case of an RA using the caches may also perform a kernel code having an irregular access pattern because the data is brought to the SPM.

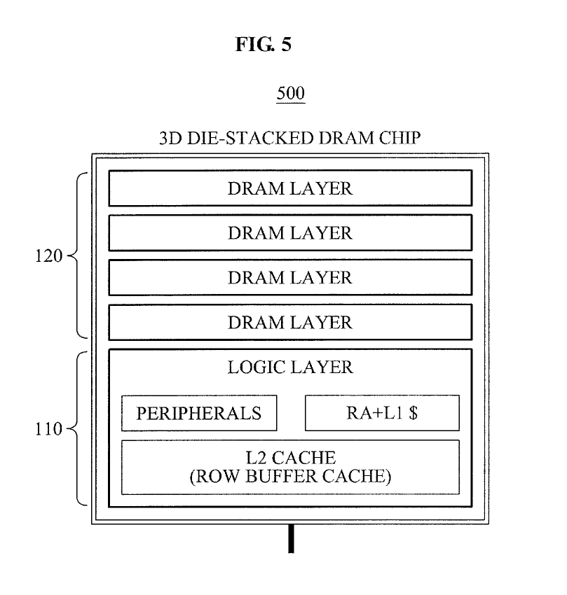

FIG. 5 is a block diagram illustrating a configuration of a memory device 500 according to still another embodiment of the present invention.

Referring to FIG. 5, the memory device 500, also referred to as a 3D die-stacked DRAM chip, includes a logic layer 110 and a data layer 120.

The logic layer 110 may include at least one of a peripheral device, an interface, and a BIST module, and an RA. The RA may be positioned in a vacant space of the logic layer 110, and process a portion of a task processed by the memory device 500.

The data layer 120 may store data and include at least one DRAM layer.

The logic layer 110 may include a local memory. The local memory may include a first local cache including a plurality of caches and a second local cache connecting the data layer 120 to the first local cache.

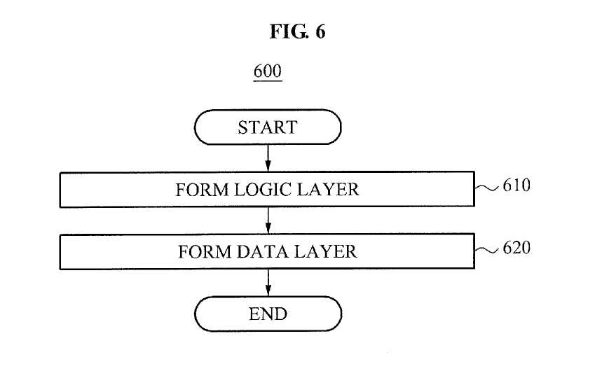

FIG. 6 is a flowchart illustrating a method of preparing a memory device according to an embodiment of the present invention.

Referring to FIG. 6, in operation 610, a logic layer of the memory device is formed. The logic layer may include a peripheral device, an interface, and a BIST module. In addition, the logic layer may include an RA. The RA may be positioned in a vacant space in the logic layer and process at least a portion of a task processed by the memory device.

In operation 620, a data layer of the memory device is formed. In an example, a plurality of data layers may be provided.

The logic layer and the data layer may be stacked using a TSV.

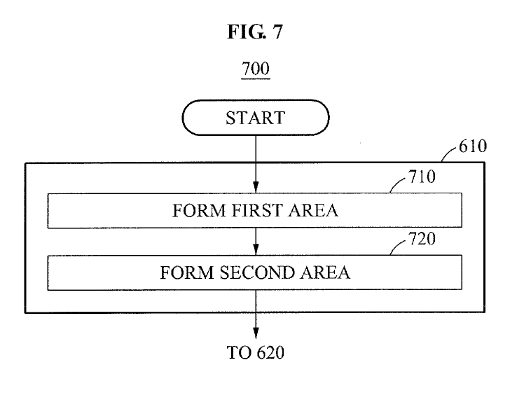

FIG. 7 is a flowchart illustrating an operation of forming a logic layer according to an embodiment of the present invention.

FIG. 7 illustrates a detailed operation of forming the logic layer described with reference to FIG. 6.

Referring to FIG. 7, in operation 710, a first area of the logic layer is formed. The first area may include at least one of a peripheral device, an interface, and a BIST module. The first area may be positioned at a center of the logic layer.

In operation 720, a second area of the logic layer is formed. The second area may include an RA. The second area may be a remaining area in the logic layer from which the first area is excluded.

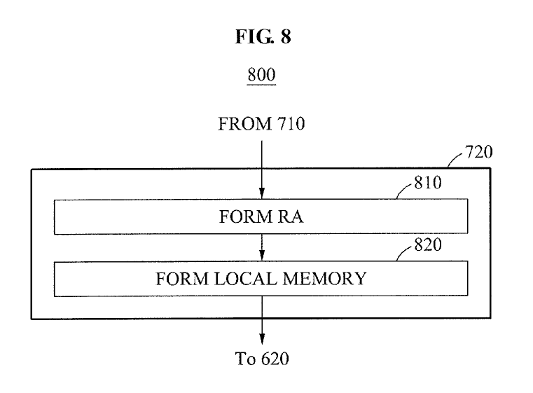

FIG. 8 is a flowchart illustrating an operation of forming a second area according to an embodiment of the present invention.

FIG. 8 illustrates a detailed operation of forming the second area described with reference to FIG. 7.

Referring to FIG. 8, in operation 810, an RA is formed in the second area. The RA may be positioned in a vacant space in the logic layer. The RA may include PEs. The PEs may be connected to one another to be in a form of an array structure.

In an example, a first PE may be connected to a second PE adjacent to the first PE, and transmit and receive data with the second PE. Each PE may include an FU to perform a data calculation.

In operation 820, a local memory is formed in the second area. The local memory may include a first local cache and a second local cache. The first local cache including a plurality of caches may be formed in the second area. In addition, the second local cache connecting a data layer to the first local cache may be formed in the second area.

The units described herein may be implemented using hardware components and software components. For example, the hardware components may include microphones, amplifiers, band-pass filters, audio to digital convertors, and processing devices. A processing device may be implemented using one or more general-purpose or special purpose computers, such as, for example, a processor, a controller and an arithmetic logic unit (ALU), a digital signal processor, a microcomputer, a field programmable array (FPA), a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums. The non-transitory computer readable recording medium may include any data storage device that can store data which can be thereafter read by a computer system or processing device. Examples of non-transitory computer-readable media include magnetic media such as hard disks, floppy disks, and magnetic tape; optical media such as CD ROM discs and DVDs; magneto-optical media such as floptical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention, or vice versa.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A memory device, comprising:
a logic layer comprising at least one of a peripheral device, an interface, and a built-in self-test (GIST) module and a reconfigurable accelerator (RA), wherein the RA is positioned in a vacant space of the logic layer and processes at least a portion of a task to be processed by the memory device; and
at least one data layer to store data.

2. The memory device of claim 1, wherein the RA comprises processing elements (PEs), and
wherein the PEs are connected to one another to be in a form of an array structure.

3. The memory device of claim 2, wherein a first PE is connected to a second PE adjacent to the first PE, and transmits and receives the data with the second PE.

4. The memory device of claim 2, wherein a PE comprises a functional unit (FU) to calculate the data.

5. The memory device of claim 1, wherein the logic layer comprises a local memory.

6. The memory device of claim 5, wherein the local memory comprises:
a first local cache comprising a plurality of caches; and
a second local cache to connect the data layer to the first local cache.

7. The memory device of claim 6, wherein, when the RA does not operate, the second local cache is used as a row buffer of the data layer.

8. The memory device of claim 1, wherein a size of the logic layer is identical to a size of the data layer.

9. The memory device of claim 1, wherein a first area comprising at least one of the peripheral device, the interface, and the BIST module is positioned at a center of the logic layer.

10. The memory device of claim 1, wherein the logic layer is disposed below the data layer.

11. A memory device, comprising:
at least one data layer to store data; and
a logic layer disposed below the at least one data layer,
wherein the logic layer comprises a first area comprising at least one of a peripheral device, an interface, and a built-in self-test (BIST) module and a second area comprising a reconfigurable accelerator (RA).

12. The memory device of claim 11, wherein the first area is positioned at a center of the logic layer, and the second area is a remaining area in the logic layer from which the first area is excluded.

13. The memory device of claim 11, wherein the logic layer and the at least one data layer are stacked using a through-silicon via (TSA).

14. The memory device of claim H, wherein the logic layer comprises a local memory.

15. The memory device of claim 14, wherein the local memory comprises:
a first local cache comprising a plurality of caches; and
a second local cache to connect the data layer to the first local cache.

16. A method of preparing a memory device, comprising:
forming a logic layer comprising a peripheral device, an interface, and a built-in self-test (BIST) module and a reconfigurable accelerator (RA), wherein the RA is positioned in a vacant space of the logic layer and processes at least a portion of a task processed by the memory device; and
forming at least one data layer storing data.

17. The method of claim 16, wherein the logic layer and the at least one data layer are stacked using a through-silicon via (TSV).

18. The method of claim 16, further comprising:
forming processing elements (PEs) in the RA to be in an array structure.

19. The method of claim 16, further comprising:
forming a local memory in the logic layer.

20. The method of claim 19, further comprising:
forming, in the local memory, a first local cache comprising a plurality of caches; and
forming, in the local memory, a second local cache connecting the data layer to the first local cache.
